(19) United States
(12) Patent Application Publication
(10) Pub. No.: US 2019/0064620 A1
(43) Pub. Date: Feb. 28, 2019

(54) DISPLAY APPARATUS

(71) Applicant: Sakai Display Products Corporation, Osaka (JP)

(72) Inventor: Akira YAMAMOTO, Osaka (JP)

(21) Appl. No.: 16/040,796

(22) Filed: Jul. 20, 2018

Related U.S. Application Data
(63) Continuation-in-part of application No. PCT/JP2016/051905, filed on Jan. 22, 2016.

(51) Int. Cl. G02F 1/1362; H01L 27/12

(52) U.S. Cl. CPC G02F 1/136259; G09G 3/3677; H01L 27/124; G02F 1/136286

(57) ABSTRACT

Provided is a display apparatus capable of narrowing a bezel of a display panel, easily repairing disconnections in data signal lines, and improving yield. The display apparatus comprises a plurality of TFTs; first source lines SL1a and SL1b arranged in parallel to each other in a row direction; second source lines SL2x and SL2y arranged in parallel to each other in a column direction at one end part of a display panel in the column direction and overlapping with the first source lines SL1a and SL1b; protruding portion 30a provided at the second source line SL2x; and protruding portion 31a provided at the second source line SL2y.

### CROSS-REFERENCE TO RELATED APPLICATION

This is a continuation-in-part of PCT international application No. PCT/JP2016/051905 filed on Jan. 22, 2016, incorporated herein by reference.

### BACKGROUND OF THE INVENTION

The present technology is related to a display apparatus comprising switching elements included in each of pixels arranged in a matrix form and data signal lines to apply a data signal to the switching elements.

A display apparatus, for example, a liquid crystal display apparatus is a flat display apparatus having excellent characteristics such as high definition, being thin, being light, and low power consumption and is widely used in, for example, a thin-screen TV, a monitor for personal computer, a digital signage display. For the display part of the display apparatus, a display panel having a switching element such as a thin-film transistor (TFT) is widely used.

A display panel such as liquid crystal display panel comprises pixels arranged in a matrix form, and the each pixel has pixel electrode. A switching element is connected to the pixel electrode. Also, the display panel comprises: a plurality of first data signal lines for applying a data signal to each switching element in each column, the plurality of first data signal lines being provided in parallel to each other in a row direction; and a source driver provided in vicinity of one end part in the column direction and connected to each one end of the plurality of the first data signal lines. In a case where disconnection occurred in the first data signal line, the data signal cannot be applied to the switching element located between the disconnection portion and the other end part in the column direction.

Therefore, the liquid crystal display panel described in JPH 8-171081 A further comprises a second data signal line overlapping with a plurality of the first data signal lines at one end part in the column direction. The second data signal line is provided for every source driver. The liquid crystal display panel also comprises a third data signal line overlapping with a plurality of the first data signal lines at the other end part in the column direction. The second data signal line and the third data signal line are connected to each other. When disconnection occurred in the first data signal line, the second data signal line is melt connected to the disconnected first data signal line at a part overlapping with the disconnected first data signal line. Also, the third data signal line is melt connected to the disconnected first data signal line at a part overlapping with the disconnected first data signal line. Thus a data signal output by the source driver can be applied, via the second data signal line and the third data signal line, to the switching element located between the disconnection portion and the other end part in the column direction.

The liquid crystal display apparatus described in JP 2003-202846 A comprises a plurality of third data signal lines (compensation lines) and a compensation output part provided in a source driver and supplying a data signal to the third data signal lines. The liquid crystal display apparatus also comprises a control means to control the source driver to supply data corresponding to a disconnected first data signal line based on address setting. Thus multiple disconnections in first data signal lines is dealt with, without providing a second data signal line.

However, in the liquid crystal display apparatus described in JPH 8-171081 A, in which one source driver is connected with only one second data signal line, when disconnections occurred in two or more lines of the first data signal lines connected to the one source driver, all of the disconnections cannot be dealt with. In addition, if two or more second data signal lines are provided, a larger space for providing them is required, and that hinders narrowing a bezel of a liquid crystal display apparatus.

Also, in the liquid crystal display apparatus described in JP 2003-202846 A, the control means to control the source driver to output a corresponding data signal and the address setting are needed; therefore, there is a problem that the structure becomes complex and dealing with disconnection is time-consuming.

### SUMMARY OF THE INVENTION

The embodiment of the present disclosure has been made in view of such circumstances, and an object is to provide a display apparatus capable of narrowing a bezel of a display panel, easily repairing disconnections in data signal lines, and improving yield.

The display apparatus according to one embodiment of the present disclosure comprises: a switching element included in each of pixels arranged in a matrix form on a display panel; a plurality of first data signal lines arranged in parallel to each other in a row direction and applying a data signal to each switching element in each line along a column direction; two second data signal lines provided at one end part of the display panel in the column direction and overlapping with a plurality of the first data signal lines, the two second data signal lines being arranged side by side in the column direction; third data signal lines provided at the other end part in the column direction and overlapping with a plurality of the first data signal lines, the third data signal lines being arranged side by side in the column direction and connected to the second data signal lines; a first protruding portion provided at a part of one of the second data signal lines and protruding toward the other one of the second data signal lines, the part of the one of the second data signal lines overlapping with one of the first data signal lines; and a second protruding portion provided at a part of the other one of the second data signal lines and protruding toward the one of the second data signal lines, the part of the other one of the second data signal lines overlapping with the other one of the first data signal lines.

According to the embodiment of the present disclosure, a display apparatus can be provided, which is capable of narrowing a bezel of a display panel, easily repairing disconnections in data signal lines, and improving yield.

### BRIEF DESCRIPTION OF THE DRAWINGS

FIG. 1 shows a block diagram of the configuration of a liquid crystal display apparatus according to Embodiment 1.

FIG. 2 shows a schematic view of two second source lines.

FIG. 3 shows repair of disconnections using the second source lines.

FIG. 4 shows a schematic view of two second source lines and a fourth source line.

FIG. 5 shows repair of disconnections using the second source lines and the fourth source line.

### DETAILED DESCRIPTION

The embodiments of the present disclosure will be described below in detail with reference to drawings showing the embodiments. In the following description, the embodiments in which the display apparatus according to the present disclosure is to be a liquid crystal display apparatus are described; however, it can be appreciated that the technology according to the present disclosure can be applied to a display apparatus other than the liquid crystal display apparatus.

### Embodiment 1

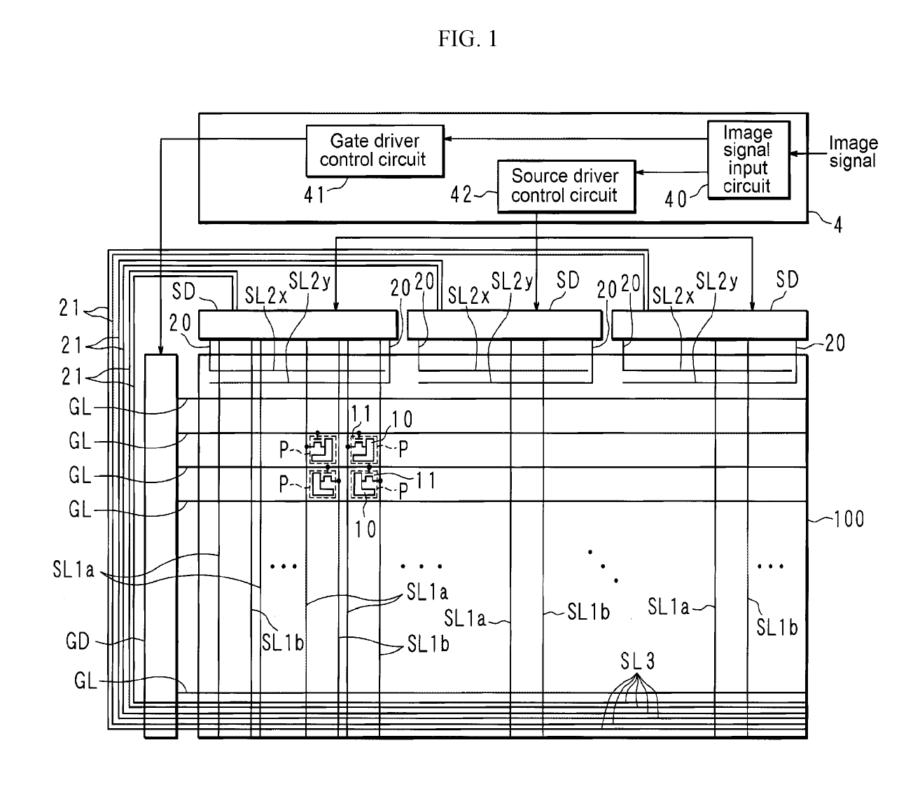

FIG. 1 shows a block diagram of the configuration of a liquid crystal display apparatus according to Embodiment 1. The liquid crystal display apparatus shown in FIG. 1 comprises a liquid crystal panel (display panel) 100 on which pixels P (each of which is shown as surrounded by a broken line in FIG. 1) are arranged in a matrix form in a column direction (the vertical direction in FIG. 1) and in a row direction (the horizontal direction in FIG. 1) on one surface thereof. It can be appreciated that some of the pixels P are shown in FIG. 1.

Each of the pixels P has a pixel electrode 10 and a counter electrode (not shown) facing the pixel electrode 10 with a liquid crystal layer (not shown) therebetween. A drain electrode of a thin-film transistor (TFT, switching element) 11 is connected to the pixel electrode 10. The pixel electrode 10 and the counter electrode form a capacitance across liquid crystal.

In each column of the pixels P, a first source line (a first data signal line) SL1a is arranged at one lateral part of the column in the row direction, and a first source line (a first data signal line) SL1b is arranged at the other lateral part of the column. Specifically, in the liquid crystal panel 100, each of the plurality of first source lines SL1a, SL1a . . . and each of the plurality of first source lines SL1b, SL1b . . . are alternatingly provided in parallel to each other in the row direction. In each column, source electrodes of TFTs 11 of alternate pixels P in the column direction are connected to the first source lines SL1a located on the one lateral part. Also, source electrodes of the TFTs 11 of the other (remaining) pixels P in each column are connected to the first source lines SL1b located on the other lateral part. In other words, the liquid crystal panel 100 is a so-called, double-source panel. It can be appreciated that. FIG. 1 shows only some of the source lines.

In the liquid crystal panel 100, a plurality of gate lines GL, GL . . . for applying a scan signal are arranged in parallel to each other in the column direction. The gate electrodes of the TFTs 11 is connected to the gate lines GL, wherein the gate electrodes of the TFTs 11 of pixels P arranged on a line along the row direction are connected to the same gate line GL. It can be appreciated that FIG. 1 shows only some of the gate lines.

The first source lines SL1a and the first source lines SL1b are separated into three groups in the row direction, and a source driver SD is provided for every group. The source drivers SD are disposed outside the liquid crystal panel 100 in vicinity of one end part of the liquid crystal panel 100 in the column direction. The source drivers SD are provided in parallel to each other in the row direction. The first source lines SL1a and SL1b are connected to each of the corresponding source drivers SD at one end thereof. Each source driver SD applies a data signal to the first source lines SL1a and SL1b connected thereto. The first source lines SL1a and SL1b apply the data signal to each switching element (TFT) in each line along the column direction of the pixels P.

The liquid crystal display apparatus comprises a gate driver GD disposed outside the liquid crystal panel 100 in vicinity of one end part of the liquid crystal panel 100 in the row direction. The gate lines GL are connected to the gate driver GD at one end thereof. The gate driver GD applies a scan signal to each of the gate lines GL.

In addition, at the one end part in the column direction of the liquid crystal panel 100, two second source lines (two second data signal lines) SL2x, SL2y are provided for each of the three source driver SD. The two second source lines SL2x, SL2y are connected to the corresponding source driver SD at one end thereof via a connecting wiring 20. The second source lines SL2x and SL2y both overlap, via an insulation film (not shown), with all of the first source lines SL1a and SL1b connected to the corresponding source driver SD. It can be appreciated that each of the second source lines SL2x and SL2y can be integrally formed with the connecting wiring 20.

In addition, at the other end part, opposite to the one end part, of the liquid crystal panel 100 in the column direction, six third source lines (third data signal lines) SL3 are provided in parallel to each other. The third source lines SL3 overlap, via an insulation film (not shown), with all of the first source lines SL1a and SL1b. In addition, each of the source drivers SD is connected to two of the third source lines SL3 via a connecting wiring 21. Also, each connecting wiring 20 and each connecting wiring 21 are connected to each other via, for example, a buffer (not shown) provided in the source driver SD so that data signal transferring is possible between the connecting wiring 20 and the connecting wiring 21. It can be appreciated that each of the third source lines SL3 and each of the connecting wiring 21 can be integrally formed.

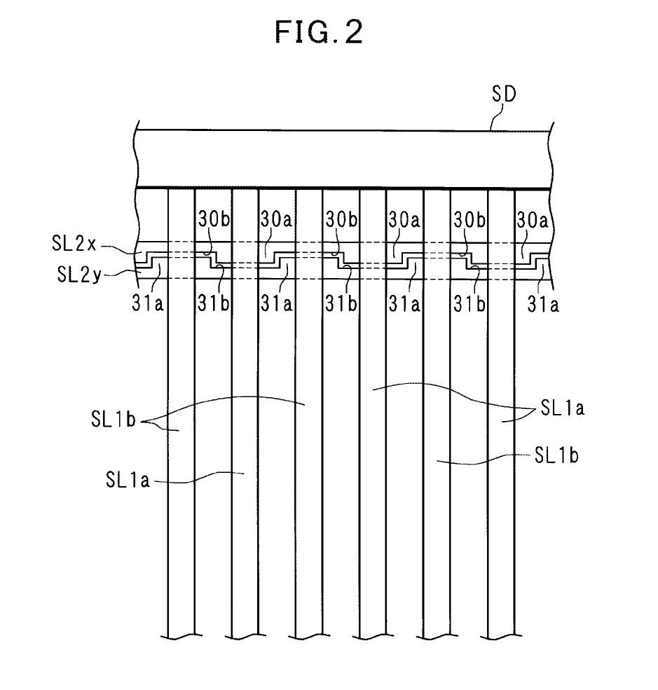

FIG. 2 shows a schematic diagram of the two second source lines SL2x, SL2y. In FIG. 2, the pixels P and the gate lines GL are not shown. The second source line SL2x has a plurality of protruding portions 30a, 30a . . . which are provided side by side in the row direction and protrude toward the second source line SL2y. Each of the protruding portions 30a overlaps with a first source line SL1a. Also, two of the protruding portions 30a adjacent to each other form a recessed portion 30b between the protruding portions 30a. In other words, the second source line SL2x is designed to have a line width being thinner at the recessed portions 30b than at the protruding portions 30a.

The second source line SL2y has a plurality of protruding portions 31a provided at parts facing the recessed portions 30b to be inserted to the recessed portions 30b. Two of the protruding portions 31a form a recessed portion 31b between the protruding portions 31a. In other words, the second source line SL2y is designed to have a line width being thinner at the recessed portions 31b than at the protruding portions 31a. Each of the protruding portions 31a overlap with the first source line SL1b adjacent to the first source line SL1a.

The protruding portions 30a of the second source line SL2x are inserted to the recessed portions 31b of the second source line SL2y, and the protruding portions 31a of the second source line SL2y are inserted to the recessed portions 30b of the second source line SL2x. The protruding portions 30a and the protruding portions 31a represent first protruding portions and second protruding portions, respectively, the recessed portions 30b and the recessed portions 31b represent first recessed portions and second recessed portions, respectively.

As shown in FIG. 1, the liquid crystal display apparatus comprises a display control circuit 4 to control, by means of the gate driver GD and the source drivers SD, display by the liquid crystal panel 100. The display control circuit 4 has an image signal input circuit 40 to receive an image signal containing image data based on images, and a gate driver control circuit 41 and a source driver control circuit 42 to control the gate driver GD and the source drivers SD, respectively based on a clock signal and a synchronizing signal separated by the image signal input circuit 40.

Each of the gate driver control circuit 41 and the source driver control circuit 42 generates control signals, for example, a start signal, a clock signal, and an enable signal which are needed for periodic operation of the gate driver GD and the source drivers SD. The source driver control circuit 42 also outputs digital image data separated by the image signal input circuit 40 to the source drivers SD.

Within one frame term in the image data, the gate driver GD sequentially applies a scan signal to the gate lines GL at predetermined time intervals, wherein the scan signal is applied to two gate lines at a time. The scan signal applied to the gate line GL is then applied to the gate electrode of the TFT 11 included in each pixel in one line of the pixels P, P . . . P arranged in the row direction.

The source drivers SD accumulate digital image data provided from the source driver control circuit 42 during one horizontal scanning period and generate data signals representing an image for one horizontal line. The generated data signals are applied in parallel to the first source lines SL1a and SL1b respectively.

The data signal applied to the first source line SL1a is applied to the pixel electrode 10 via the TFT 11 during one horizontal scanning period in which a scan signal is applied to the gate line GL corresponding to the first source line SL1a. Also, the data signal applied to the first source line SL1b is applied to the pixel electrode 10 via the TFT 11 during one horizontal scanning period in which a scan signal is applied to the gate line GL corresponding to the first source line SL1b. Thus the data signal is applied to each capacitance across liquid crystal formed in each of the pixels P.

In the manufacturing process of the liquid crystal display apparatus, when disconnection occurred in any of the first source lines SL1a and SL1b, repair is required due to a risk for display defect. In such case, repair can be performed using the second source lines SL2x and SL2y as described in the following.

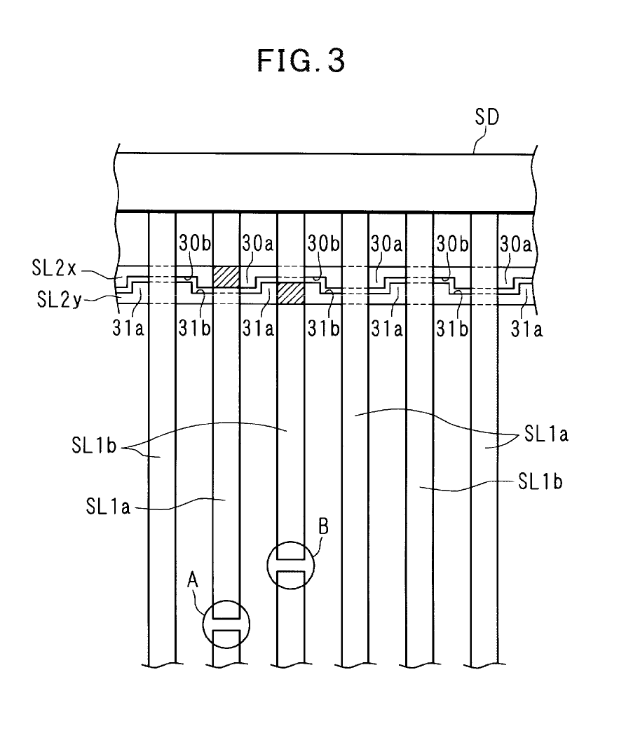

FIG. 3 shows repair of disconnections using the second source lines SL2x and SL2y. In FIG. 3, a disconnection portion A occurs in one of the first source lines SL1a, also a disconnection portion B occurs in one of the first source lines SL1b adjacent to the one of the first source lines SL1a. In FIG. 3, the pixels P and the gate lines GL are not shown.

The one of the first source lines SL1a having the disconnection portion A and the second source line SL2x overlapping with the one of the first source lines SL1a at a protruding portion 30a are melt-connected by means of, for example, laser melting at a part (with oblique lines in FIG. 3) where the both source line SL1a and SL2x are overlapping each other. Also, the one of the first source lines SL1a and a third source line SL3 corresponding (for example, connected via the connecting wirings 20, 21) to the second source line SL2x are melt-connected at a part where the both source line SL1a and SL3 are overlapping each other. Thus, a data signal applied from the source driver SD to the one of the first source lines SL1a is applied to the TFT 11 of pixel(s) P located between the disconnection portion A and the other end part in the column direction via the second source line SL2x, and the connecting wirings 20, 21 and the third source line SL3 which correspond to the second source line SL2x.

Also, the one of the first source lines SL1b having the disconnection portion B and the second source line SL2y overlapping with the one of the first source lines SL1b at a protruding portion 31a are melt-connected at a part (with oblique lines in FIG. 3) where the both source line SL1b and SL2y are overlapping each other. The one of the first source lines SL1b and a third source line SL3 corresponding to the second source line SL2y are melt-connected at a part where the both source line SL1b and SL3 are overlapping each other. Thus, a data signal applied from the source driver SD to the one of the first source lines SL1b is applied to the TFT 11 of pixel(s) P located between the disconnection portion B and the other end part in the column direction via the second source line SL2y, and the connecting wirings 20, 21 and the third source line SL3 which correspond to the second source line SL2y.

According to the above-mentioned configuration, the two second source lines SL2x, SL2y have protruding portions 30a and protruding portions 31a, and the protruding portions 30a and the protruding portions 31a are arranged in corresponding recessed portions 30b or recessed portions 31b. Also the second source lines SL2x and SL2y can surely obtain certain parts for melt-connection with a first source lines SL1a and SL1b at the protruding portion 30a or 31a. Therefore, there is no need for the second source line SL2x to have a part for melt-connection at the recessed portion 30b, and there is no need for the second source line SL2y to have a part for melt-connection at the recessed portion 31b. Accordingly, the second source lines SL2x and SL2y can be designed to have thinner widths. Also, as the two second source lines SL2x, SL2y are provided, repair is possible even when disconnections occurred in two lines of the first source lines SL1a and SL1b. Thus the configuration makes it possible to narrow bezel of a display panel, and disconnections of both the first source lines SL1a and SL1b can be easily repaired and the yield for the display apparatus can be improved.

It can be appreciated that disconnection portions are not limited to the disconnection portions A, B shown in FIG. 3, and disconnections in any two first source lines including one first source line SL1a and one first source line SL1b respectively in each of the source drivers SD can be repaired in the same way. Also, three or more second source lines are possible, and the numbers of the connecting wirings 20, 21 and the third source lines SL3 are not limited to those shown in the drawings, and can be any number as long as the number corresponds to the number of the second source lines.

### Embodiment 2

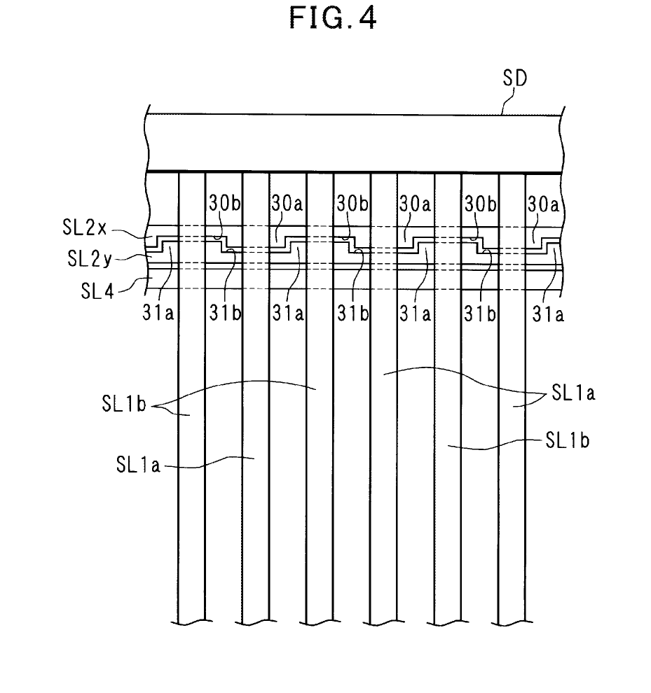

In Embodiment 2, a fourth source line is provided in parallel to the second source lines. In the configuration of the liquid crystal display apparatus of Embodiment 2, elements similar to those in the configuration of Embodiment 1 are assigned with the same reference signs, and are not described below. FIG. 4 shows a schematic view of two second source lines SL2x, SL2y and a fourth source line (a fourth data signal line) SL4. In FIG. 4, the pixels P and the gate lines GL are not shown.

In Embodiment 2, the second source lines SL2x and SL2y are arranged side by side as in Embodiment 1, and, in addition, the fourth source line SL4 is arranged in parallel, in the column direction, to the second source lines SL2x and SL2y. Also, the fourth source line SL4 overlaps with the first source lines SL1a and SL1b which overlap with the second source lines SL2x and SL2y. The liquid crystal panel 100 further comprises a third source line (not shown in FIG. 4) corresponding to the fourth source line SL4 in the same way as that corresponding to the second source lines SL2x and SL2y. The fourth source line SL4 is connected to the third source line via wiring(s) and a buffer in the source drivers SD (not shown) in the similar manner to the second source lines SL2x and SL2y.

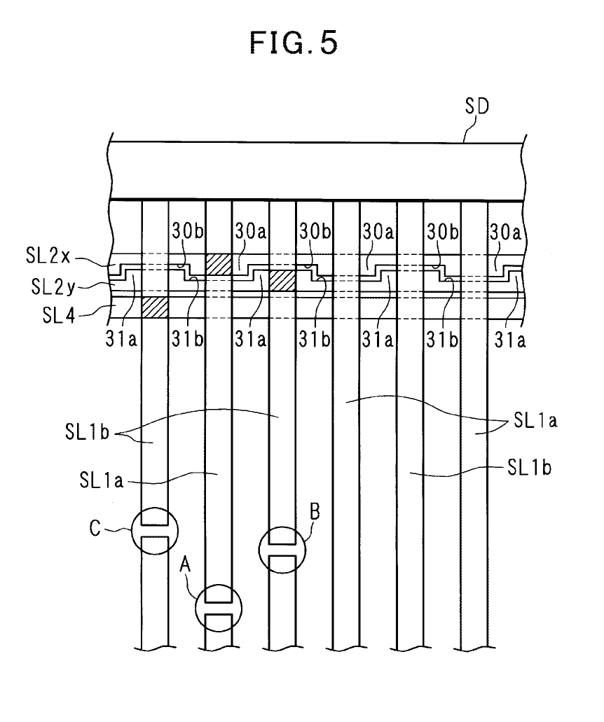

FIG. 5 shows repair of disconnections using the second source lines SL2x and SL2y and the fourth source line SL4. In FIG. 5, a disconnection portion A occurs in one of the first source line SL1a, also a disconnection portion B occurs in one first source line SL1b adjacent to the one of the first source line SL1a. Furthermore, a disconnection portion C occurs in another of the first source lines SL1b adjacent to the one of the first source lines SL1a.

In the first source lines SL1a and SL1b having the disconnection portion A and the disconnection portion B, in the similar manner to Embodiment 1, the disconnections can be repaired by melt-connecting the first source lines SL1a and SL1b having the disconnection portions A and B with the second source lines SL2x and SL2y (at the part with oblique lines in FIG. 5) and melt-connecting those two first source lines SL1a and SL1b with corresponding third source lines SL3. In the another of the first source lines SL1b having the disconnection portion C, the disconnection can be repaired by melt-connecting the another of the first source lines SL1b with the fourth source line SL4 at a part (with oblique lines in FIG. 5) where those two source lines SL1b and SL4 overlap each other and melt-connecting the another of the first source lines SL1b with a corresponding third source line SL3 (which is, for example, connected to the fourth source line SL4 via a wiring and a buffer in the source driver SD (not shown)). Therefore, the fourth source line SL4 is used for repair of disconnection in the similar manner to the second source lines SL2x and SL2y. Therefore, in Embodiment 2, disconnections which occur in three lines of the first source lines SL1a and SL1b can be dealt with.

The configuration mentioned above allows for the design of the second source lines SL2x and SL2y having thinner widths in the similar manner to Embodiment 1, and thus it is possible to narrow a bezel of a display apparatus even with the fourth source line SL4. Also, because the two second source lines SL2x, SL2y and the fourth source line SL4 are provided in parallel to each other, it is possible to deal with disconnections which occur in three lines among the first source lines SL1a and SL1b.

It can be appreciated that disconnection portions are not limited to the disconnection portions A, B, C shown in FIG. 5, and disconnections in any three first source lines including at least one first source line SL1a and at least one first source line SL1b respectively can be repaired in the same way. Also, two or more fourth source lines are possible, and the number of third source lines and the number of wiring connecting the third source lines with second source lines and the fourth source lines can be any number as long as the number corresponds to the numbers of the second source lines and the fourth source lines.

It can be appreciated that, in the above-mentioned Embodiment 1 and Embodiment 2, the number of the source drivers is not limited to three, but can be two or less, or four or more. Also, the liquid crystal panel 100 is not limited to a double-source panel. In addition, the protruding portions 30a and 31a can be formed so as to overlap with not one first source line SL1a and one first source line SL1b but a plurality of the first source lines SL1a and a plurality of first source lines SL1b respectively. In this case, the recessed portions 30b, 31b are sized to correspond to the sizes of the protruding portions 30a, 31a, respectively. Also, the number of the first source lines SL1a and SL1b which overlap with one protruding portion 30a can be different from the number of the first source lines SL1a and SL1b which overlap the protruding portion 31a disposed adjacent to the one protruding portion 30a. In addition, as mentioned above, a display apparatus to which the technology according to the present disclosure can be applied is not limited to a liquid crystal display apparatus, the technology can be also applied to, for example, an organic EL display apparatus.

It should be appreciated that the embodiments in the present disclosure are intended to be illustrative and not restrictive in all respects. The scope of the present invention is not limited to the above-described context, and is defined by the claims, and the meaning equivalent to the claims and all modifications within the scope of the claims are intended to be included. In other words, embodiments obtained by combining technical means appropriately changed within the scope specified by claims are also included in the technical scope of the present invention.

What is claimed is:

1. A display apparatus comprising:
a switching element included in each of pixels arranged in a matrix form on a display panel;
a plurality of first data signal lines arranged in parallel to each other in a row direction and applying a data signal to each switching element in each line along a column direction;
two second data signal lines provided at one end part of the display panel in the column direction and overlapping with a plurality of the first data signal lines, the two second data signal lines being arranged side by side in the column direction;
third data signal lines provided at the other end part in the column direction and overlapping with a plurality of the first data signal lines, the third data signal lines being arranged side by side in the column direction and connected to the second data signal lines;
a first protruding portion provided at a part of one of the second data signal lines and protruding toward the other one of the second data signal lines, the part of the one of the second data signal lines overlapping with one of the first data signal lines; and
a second protruding portion provided at a part of the other one of the second data signal lines and protruding toward the one of the second data signal lines, the part of the other one of the second data signal lines overlapping with the other one of the first data signal lines.

2. The display apparatus of claim 1, wherein the display apparatus comprises a plurality of the first protruding portion and a plurality of the second protruding portion, and the one of the first data signal lines and the other one of the first data signal lines are adjacent to each other.

3. The display apparatus of claim 2, wherein, a first recessed portion is formed between the first protruding portions adjacent to each other, and the second protruding portion is inserted to the first recessed portion; and a second recessed portion is formed between the second protruding portions adjacent to each other, and the first protruding portion is inserted to the second recessed portion.

4. The display apparatus of claim 3, wherein a line width of the one of the second data signal lines is thinner at the first recessed portion than at the first protruding portion, and a line width of the other one of the second data signal lines is thinner at the second recessed portion than at the second protruding portion.

5. The display apparatus of claim 1, further comprising a fourth data signal line provided at the one end part and overlapping with a plurality of the first data signal lines, the fourth data signal line and the two second data signal lines being arranged in the column direction and in parallel to each other.
